(19) United States
(12) Patent Application Publication
(10) Pub. No.: US 2025/0112096 A1
(43) Pub. Date: Apr. 3, 2025

(54) Inspection Method

(71) Applicant: Tokyo Electron Limited, Tokyo (JP)

(72) Inventor: Hiroyuki NAKAYAMA, Yamanashi (JP)

(21) Appl. No.: 18/981,261

(22) Filed: Dec. 13, 2024

Related U.S. Application Data
(63) Continuation of application No. PCT/JP2023/022194, filed on Jun. 15, 2023.

(30) Foreign Application Priority Data
Jun. 29, 2022 (JP) 2022-105056

(51) Int. Cl. H01L 21/66; H01L 21/67

(52) U.S. Cl. CPC H01L 22/12; H01L 21/67103

(57) ABSTRACT

Provided is an inspection method for inspecting an inspection object of a first substrate, comprising: (a) preparing the first substrate having a first electrode connected to the inspection object; (b) preparing a second substrate having a second electrode and a bonding portion which are formed on a first main surface, and having a third electrode formed on a second main surface opposite to the first main surface and electrically connected to the second electrode; (c) bringing the first electrode and the second electrode into electrical contact with each other and forming a sealed space between the first substrate and the second substrate by bonding the first substrate and the second substrate with an adhesive interposed therebetween; (d) curing the adhesive; (e) inspecting the inspection object; and (f) separating the first substrate from the second substrate.

### CROSS-REFERENCE TO RELATED APPLICATIONS

This application is a bypass continuation application of International Application No. PCT/JP2023/022194 having an international filing date of Jun. 15, 2023 and designating the United States, the International Application being based upon and claiming the benefit of priority from the Japanese Patent Application No. 2022-105056 filed on Jun. 29, 2022, the entire contents of which are incorporated herein by reference.

### TECHNICAL FIELD

The present disclosure relates to an inspection method.

### BACKGROUND

For example, Japanese Laid-open Patent Publication Nos. 2020-194856 and 2020-198354 disclose a shell having a wafer (inspection substrate) and a probe card (contact substrate).

### SUMMARY

The present disclosure provides an inspection method capable of efficiently reusing a contact substrate.

In accordance with an aspect of the subject application, there is provided an inspection method for inspecting an inspection object of a first substrate, comprising: (a) preparing the first substrate having a first electrode connected to the inspection object; (b) preparing a second substrate having a second electrode and a bonding portion which are formed on a first main surface, and having a third electrode formed on a second main surface opposite to the first main surface and electrically connected to the second electrode; (c) bringing the first electrode and the second electrode into electrical contact with each other and forming a sealed space between the first substrate and the second substrate by bonding the first substrate and the second substrate with an adhesive interposed therebetween; (d) curing the adhesive; (e) inspecting the inspection object; and (f) separating the first substrate from the second substrate, wherein in said (f), a bonding strength of the adhesive with respect to the first substrate is higher than a bonding strength of the adhesive with respect to the second substrate at the time of being separated the first substrate from the second substrate.

### BRIEF DESCRIPTION OF THE DRAWINGS

FIG. 1 shows an example of an overall configuration of an inspection system according to the present embodiment.

FIG. 2 is a cross-sectional view of a shell used in the inspection system according to the present embodiment.

FIG. 3 is a flowchart of an inspection method according to the present embodiment.

FIG. 4 illustrates the inspection method according to the present embodiment.

FIG. 5 illustrates the inspection method according to the present embodiment.

FIG. 6 illustrates the inspection method according to the present embodiment.

FIG. 7 illustrates the inspection method according to the present embodiment.

FIG. 8 illustrates the inspection method according to the present embodiment.

FIG. 9 illustrates the inspection method according to the present embodiment.

FIG. 10 illustrates the inspection method according to the present embodiment.

FIG. 11 illustrates a modification of the inspection method according to the present embodiment.

### DETAILED DESCRIPTION

Hereinafter, embodiments will be described with reference to the accompanying drawings. Further, the scope of the present disclosure is presented not by the description the following embodiments but by the scope of claims, and is intended to include all modifications within the meaning and scope of equivalent to those of the claims.

Further, in the description of the specification and drawings relating to each embodiment, like or corresponding reference numerals may be used for components having substantially the same or corresponding functional configurations to omit redundant description. Further, for ease of understanding, the scale of individual components in the drawings may be different from the actual scale.

First, an overall configuration of an inspection system that performs inspection will be described. The inspection system is a system that applies electrical signals to a plurality of devices under test (DUT) formed on an inspection object to inspect various electrical characteristics of the devices. The inspection object is, for example, a substrate such as a semiconductor wafer (hereinafter, referred to as “wafer”).

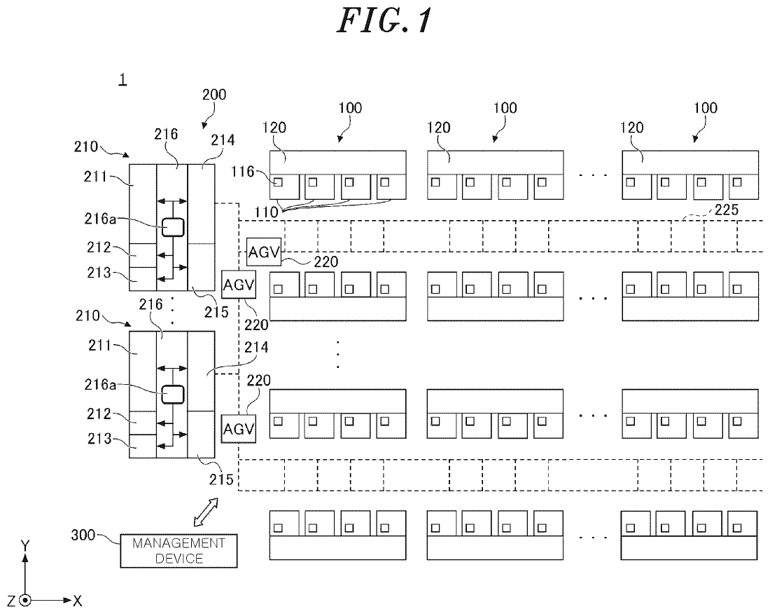

FIG. 1 shows an example of the overall configuration of the inspection system. As shown in FIG. 1, an inspection system 1 includes a plurality of inspection units 100, a transfer system 200, and a management device 300.

The inspection units 100 are arranged side by side in the same plane, in the left-right direction (X direction in FIG. 1) and the front-back direction (Y direction in FIG. 1). Each of the inspection units 100 includes a plurality of inspection devices 110 and a chiller 120.

Each of the inspection devices 110 receives a shell 5 transferred by a cassette unit 220 to be described later, and inspects the electrical characteristics of each DUT formed on the inspection substrate 10. Each of the inspection devices 110 includes a controller 116 that controls the overall operation of the inspection device 110. The shell 5 will be described later.

The chiller 120 cools a stage by supplying a coolant such as cooling water to coolant channels provided at stages of the plurality of inspection devices 110. In the example of FIG. 1, one chiller 120 is provided for four inspection devices 110. However, the chiller 120 may be provided for each inspection device 110.

The transfer system 200 includes a plurality of loader units 210 and a plurality of cassette units 220.

The plurality of loader units 210 are arranged side by side in the same plane in the front-rear direction (Y direction in FIG. 1). Each loader unit 210 includes a front opening unified pod (FOUP) stocker 211, a probe card stocker 212, a needle polishing part 213, a shell stocker 214, an attachment/detachment part 215, and a transfer part 216.

The FOUP stocker 211 is an area for storing a transfer container (FOUP) that accommodate a plurality of inspection substrates 10. The FOUP stocker 211 is provided with, for example, a plurality of storage shelves for storing FOUPs. The FOUP is loaded into the FOUP stocker 211 from the outside of the inspection system 1. The FOUP stocker 211 can be accessed by a transfer device 216a of a transfer part 216 to be described later.

The probe card stocker 212 is an area for storing a plurality of contact substrates 20. The probe card stocker 212 is provided with, for example, a plurality of storage shelves for storing the contact substrates 20. The contact substrate 20 is loaded into the probe card stocker 212 from the outside of the inspection system 1. The probe card stocker 212 can be accessed by the transfer device 216a of the transfer part 216 to be described later.

The needle polishing part 213 is an area where probes with dust or the like attached thereto are repaired by polishing tips of the probes of the contact substrate 20. The needle polishing part 213 is provided with, for example, a needle polishing plate for polishing the tips of the probes. The needle polishing part 213 can be accessed by the transfer device 216a of the transfer part 216 to be described later.

The shell stocker 214 is an area for storing a plurality of shells 5. The shell stocker 214 is provided with, for example, a plurality of storage shelves for storing the shells 5. The shell stocker 214 stores the shells 5 formed at the attachment/detachment part 215 and the shells 5 that have been inspected by the inspection unit 100. The shell stocker 214 can be accessed by the transfer device 216a of the transfer part 216 to be described later, and the cassette unit 220.

The attachment/detachment part 215 is an area where the shell 5 in which the inspection substrate 10 and the contact substrate 20 are integrated is formed, and where the shell 5 is separated into the inspection substrate 10 and the contact substrate 20. In the attachment/detachment part 215, the inspection substrate 10 is positioned by an aligner while being attracted and held on the placing table, and the corresponding probes of the contact substrate 20 are brought into contact with and connected to the electrodes of the plurality of DUTs, thereby forming the shell 5. Further, in the attachment/detachment part 215, the inspection substrate 10 and the contact substrate 20 integrated into the shell 5 are separated. The attachment/detachment part 215 can be accessed by the transfer device 216a of the transfer part 216 to be described later.

The transfer part 216 is an area where the shell 5, the inspection substrate 10, and the contact substrate 20 are transferred between the respective areas. The transfer part 216 is provided with the transfer device 216a that transfers the shell 5, the inspection substrate 10, and the contact substrate 20. The transfer device 216a holds the shell 5, the inspection substrate 10, and the contact substrate 20 and transfers them between the respective areas. For example, the transfer device 216a transfers the shell 5 between the attachment/detachment part 215 and the shell stocker 214. Further, the transfer device 216a transfers the inspection substrate 10 between the FOUP stocker 211 and the attachment/detachment part 215. Further, the transfer device 216a transfers the contact substrate 20 between the probe card stocker 212, the needle polishing part 213, and the attachment/detachment part 215.

The plurality of cassette units 220 are mobile units, each of which stores the plurality of shells 5 and supplies the shells 5 to the plurality of inspection units 100. In the example of FIG. 1, the plurality of cassette units 220 transfer the shells between the shell stocker 214 of the loader unit 210 and the stage 111 of the inspection device 110. The cassette unit 220 is, for example, an automated guided vehicle (AGV). The cassette unit 220 moves by itself along a guide line 225 such as a magnetic tape on a floor.

The management device 300 controls the operations of the plurality of cassette units 220 based on the position information of the plurality of cassette units 220 measured by a positioning device (not shown). The management device 300 determines a cassette unit 220 to be directed to the inspection device 110 based on the position information of the plurality of cassette units 220 measured by the positioning device. For example, the management device 300 directs the cassette unit 220 located closest to the target inspection device 110 to the inspection device 110.

Further, the management device 300 calculates the optimal route for transferring the shell 5 to the determined cassette unit 220, and operates the cassette unit 220 along the optimal route. Further, the management device 300 may obtain the number of shells 5 stored in each cassette unit 220 and control the operations of the plurality of cassette units 220 based on the obtained number of shells 5. For example, the cassette units 220 where the obtained number of shells 5 is large are operated first.

The positioning device may be of any type, as long as it can measure the position information of the plurality of cassette units 220. The positioning device may be, for example, a plurality of position detection sensors that are disposed on the guide line 225 and capable of detecting the passage of the cassette unit 220. Further, the positioning device may be a global navigation satellite system (GNSS) receiver. The GNSS receiver is mounted on each cassette unit 220, and receives a positioning signal from a GNSS satellite, such as a global positioning system (GPS) satellite, and obtain the position information of the cassette unit 220, for example.

### (Shell)

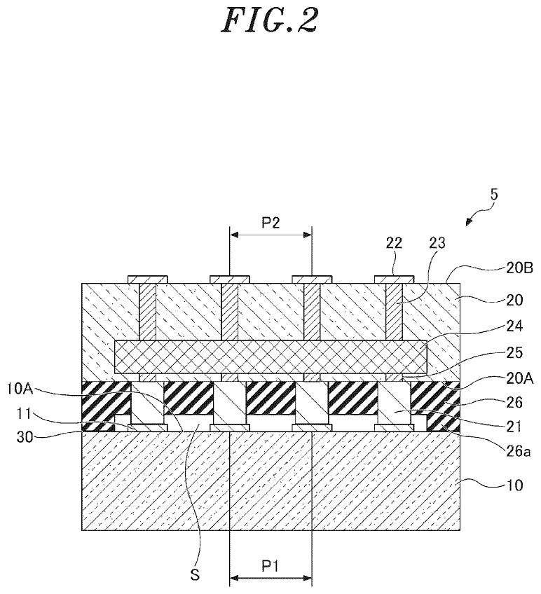

Next, an example of the configuration of the shell 5 will be described. FIG. 2 shows an example of the shell 5. FIG. 2 is a cross-sectional view showing the shell 5. The shell 5 includes the inspection substrate 10 and the contact substrate 20. The inspection substrate 10 and the contact substrate 20 are bonded with an adhesive 30.

The inspection substrate 10 is a semiconductor substrate such as a silicon substrate, a silicon carbide substrate, or the like. A plurality of devices under test (DUT) are formed on the inspection substrate 10. Each DUT includes an electrode pad 11.

A plurality of electrode pads 11 are formed on a first main surface 10A of the inspection substrate 10. Each electrode pad 11 is made of a metal such as aluminum (AI), copper (Cu), or the like. Each electrode pad 11 has a surface where an insulating layer such as an oxide film is removed by surface treatment to expose the metal constituting the electrode pad 11. Metal bumps may be formed on each electrode pad 11, or metal bumps may be formed instead of the electrode pads 11. When metal bumps are formed instead of the electrode pads 11, the metal bumps have a surface where the insulating layer such as an oxide film is removed by surface treatment to expose the metal constituting the metal bump. The electrode pads 11 are arranged at a first pitch P1. The first pitch P1 is, for example, 10 micrometers or less.

The contact substrate 20 is bonded to the inspection substrate 10 by the adhesive 30. It is preferable that the contact substrate 20 has the same thermal expansion coefficient as that of the inspection substrate 10. Since the contact substrate 20 has the same thermal expansion coefficient as that of the inspection substrate 10, it is possible to suppress the occurrence of misalignment between the electrode pads 11 and contact portions 21 when the temperature of the shell 5 changes. It is preferable that the contact substrate 20 is made of the same material as that of the inspection substrate 10. The contact substrate 20 is, for example, a semiconductor substrate such as a silicon substrate, a silicon carbide substrate, or the like. Further, the contact substrate 20 may be a glass substrate having the same thermal expansion coefficient as that of the inspection substrate 10, or a substrate in which a semiconductor substrate and a glass substrate are laminated. The contact substrate 20 has the plurality of contact portions 21, a plurality of electrode pads 22, a plurality of wirings 23, an internal circuit 24, a plurality of wirings 25, and an insulating layer 26.

The contact portions 21 are formed on a first main surface 20A. The first main surface 20A is a surface facing the first main surface 10A of the inspection substrate 10. The contact portions 21 are arranged at the same pitch as that of the electrode pads 11. By arranging the contact portions 21 at the same pitch as that of the electrode pads 11, the respective contact portions 21 are brought into electrical contact with the corresponding electrode pads 11. The contact portions 21 are made of a conductive material such as copper (Cu), carbon (C), or the like.

The plurality of electrode pads 22 are formed on a second main surface 20B. The second main surface 20B is a surface facing the first main surface 20A. The electrode pads 22 are arranged at a second pitch P2. The second pitch P2 is greater than equal to the first pitch P1, and is within a range of, for example, 50 micrometers to 500 micrometers. In FIG. 2, for convenience of explanation, the first pitch P1 and the second pitch P2 are shown as the same pitch. The electrode pads 22 are electrically connected to the contact portions 21 via the wirings 23. The electrode pads 22 are made of a metal such as aluminum (AI), copper (Cu), or the like. The electrode pads 22 may be formed by plating the metal with gold (Au) or the like.

The plurality of wirings 23 electrically connect the plurality of electrode pads 22 to the internal circuit 24. Each of the wirings 23 is made of a metal such as copper (Cu) or the like. The plurality of wirings 25 electrically connect the plurality of contact parts 21 to the internal circuit 24. Each of the wirings 25 is made of a metal such as copper (Cu) or the like.

The internal circuit 24 may include, for example, a through-silicon via (TSV), a redistribution layer (RDL), a through-glass via (TGV), or the like. Since the internal circuit 24 includes the TSV, the RDL, the TGV, or the like, the plurality of contact parts 21 can be rewired by the internal circuit 24 and can be electrically connected to the plurality of electrode pads 22. Since the plurality of contact parts 21 are rewired by the internal circuit 24 and electrically connected to the plurality of electrode pads 22, the pitch of the plurality of electrode pads 22 can be further increased.

The insulating layer 26 is formed on the first main surface 20A. The insulating layer 26 is formed to cover the area of the first main surface 20A where the contact parts 21 are not formed. The insulating layer 26 is made of an insulating material such as silicon oxide (SiO₂) or polyimide (PI).

The insulating layer 26 includes a bonding portion 26a. The bonding portion 26a is formed at the periphery of the first main surface 20A. The bonding portion 26a protrudes from the surface of the insulating layer 26 toward the inspection substrate 10. The bonding portion 26a is bonded to the first main surface 10A of the inspection substrate 10 by an adhesive 30, thereby forming a sealed space S between the inspection substrate 10 and the contact substrate 20.

The area where the electrode pads 11 and the contact portions 21 are in contact with each other is surrounded by the sealed space S. The sealed space S is preferably maintained in a decompressed atmosphere or an inert gas atmosphere. By maintaining the sealed space S in a decompressed atmosphere or an inert gas atmosphere, the plurality of electrode pads 11 are prevented from being exposed to the atmosphere. Since the electrode pads 11 are prevented from being exposed to the atmosphere, oxidation of the surfaces of the electrode pads 11 can be suppressed. In other words, the generation of a natural oxide film on the surfaces of the electrode pads 11 can be suppressed. Further, the bonding portion 26a may be separate from the insulating layer 26, and may be made of a material different from that of the insulating layer 26.

The adhesive 30 bonds the inspection substrate 10 and the contact substrate 20. The adhesive 30 is, for example, a photocurable resin that is cured by ultraviolet light. Further, the adhesive 30 is a resin that can be peeled off by heating. For example, an adhesive that is cured by ultraviolet light and whose bonding strength decreases by heating at a temperature of 200° C. or higher for 10 minutes may be used as the adhesive 30.

### (Inspection Method)

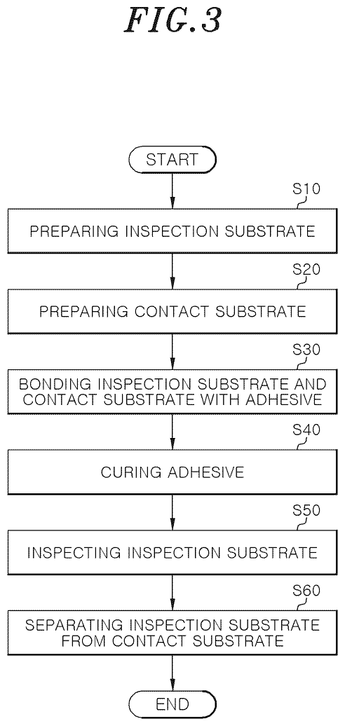

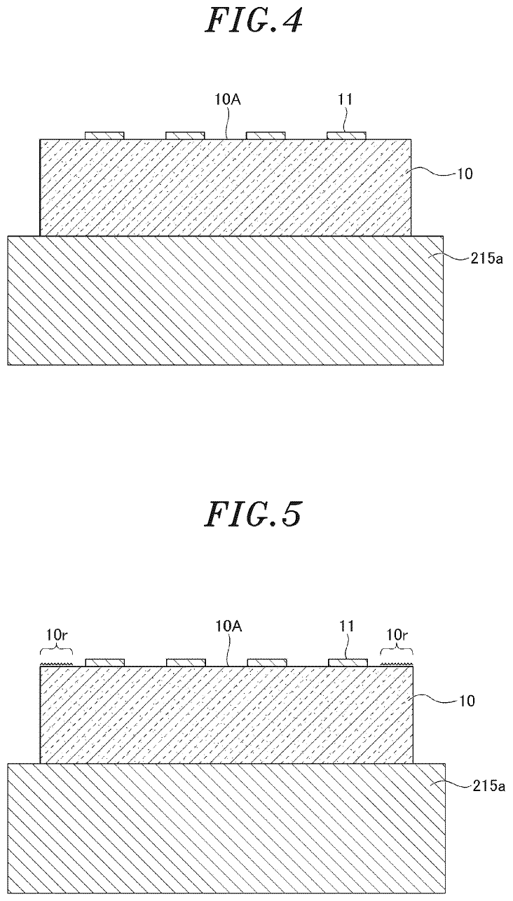

The inspection method of the inspection substrate 10 according to the present embodiment will be described. FIG. 3 is a flowchart for explaining the inspection method of the inspection substrate 10 according to the present embodiment. FIGS. 4 to 10 explain the inspection method of the inspection substrate 10 according to the present embodiment. FIGS. 4 to 10 are cross-sectional views of the inspection substrate 10, the contact substrate 20, and a placing table 215a.

### (Step S10)

First, the inspection substrate 10 is prepared (step of preparing the inspection substrate). The inspection substrate 10 is transferred from the FOUP stocker 211 to the attachment/detachment part 215 by the transfer device 216a of the transfer part 216. Then, the inspection substrate 10 is placed on the placing table 215a of the attachment/detachment part 215. FIG. 4 shows a state in which the inspection substrate 10 is placed on the placing table 215a of the attachment/detachment part 215.

### (Step S20)

Next, the contact substrate 20 is prepared (step of preparing the contact substrate). The contact substrate 20 is transferred from the probe card stocker 212 to the attachment/detachment part 215 by the transfer device 216a of the transfer part 216.

### (Step S30)

Next, the inspection substrate 10 and the contact substrate 20 are bonded with the adhesive 30 (step of bonding the inspection substrate and the contact substrate with an adhesive).

First, surface treatment is performed, as pretreatment for bonding, on an area 10r of the first main surface 10A of the inspection substrate 10 that is brought into contact with the bonding portion 26a of the contact substrate 20. The surface treatment is, for example, plasma activation treatment or coupling treatment. The surface treatment is treatment for increasing the bonding strength of the adhesive with respect to the inspection substrate 10. FIG. 5 shows a state in which the surface treatment is performed on the area 10r of the inspection substrate 10. In FIG. 5, the area where the surface treatment is performed is indicated by dashed lines.

By performing the surface treatment on the area 10r of the inspection substrate 10, the bonding strength of the adhesive 30 with respect to the inspection substrate 10 is increased. By increasing the bonding strength of the adhesive 30 in the area 10r of the inspection substrate 10, when the contact substrate 20 is separated from the inspection substrate 10, the bonding strength of the adhesive with respect to the inspection substrate 10 becomes higher than the bonding strength of the adhesive 30 with respect to the contact substrate 20. Therefore, when the contact substrate 20 is separated from the inspection substrate 10, the adhesive can be prevented from being adhered to the contact substrate 20.

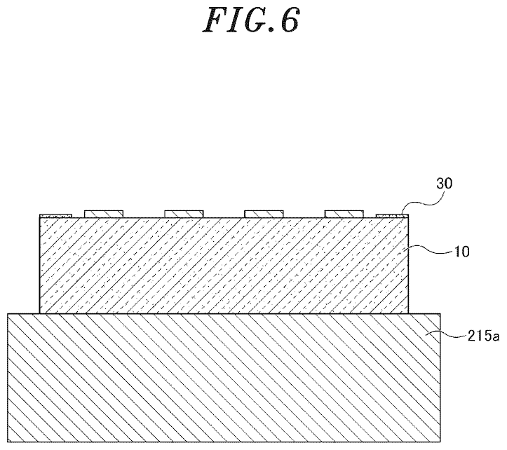

Next, the adhesive 30 is applied to the area 10r of the first main surface 10A of the inspection substrate 10, which is brought into contact with the bonding portion 26a of the contact substrate 20. FIG. 6 shows a state in which the adhesive is applied to the area 10r of the inspection substrate 10.

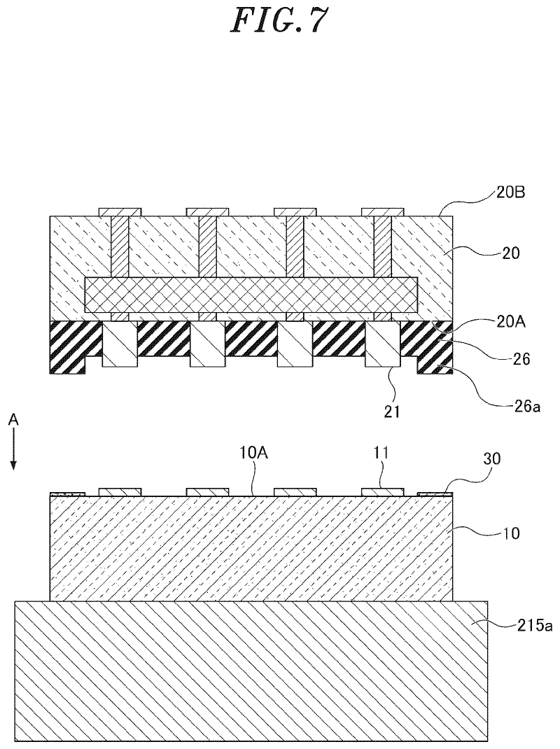

Then, the contact substrate 20 is disposed such that the first main surface 20A of the contact substrate 20 faces the first main surface 10A of the inspection substrate 10. FIG. 7 shows a state in which the first main surface 20A of the contact substrate 20 faces the first main surface 10A of the inspection substrate 10. The contact substrate 20 is disposed above the inspection substrate 10 by a robot arm or the like, for example. The contact substrate 20 is aligned such that the electrode pads 11 and the contact parts 21 corresponding to the electrode pads 11 are in contact with each other.

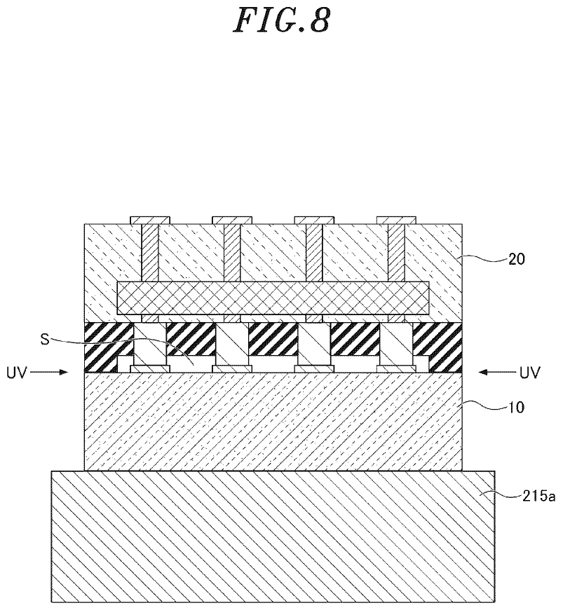

Then, the contact substrate 20 is moved in the direction of an arrow A in FIG. 7, so that the contact substrate 20 is placed on the inspection substrate 10. FIG. 8 shows a state in which the contact substrate 20 is placed on the inspection substrate 10. By placing the contact substrate 20 on the inspection substrate 10, the inspection substrate 10 and the contact substrate 20 are bonded by the adhesive 30 with the bonding portion 26a interposed therebetween. Further, by placing the contact substrate 20 on the inspection substrate 10, the sealed space S is formed.

### (Step S40)

Next, the adhesive 30 is cured by irradiating ultraviolet light from an external light source thereto (step of curing the adhesive). The ultraviolet light is irradiated along an arrow UV in FIG. 8. When the adhesive 30 is cured, the assembly of the shell 5 is completed. The assembled shell 5 is transferred from the attachment/detachment part 215 to the shell stocker 214 by the transfer device 216a of the transfer part 216.

### (Step S50)

Next, the shell 5 is used for inspecting the inspection substrate 10 (step of inspecting the inspection substrate). The shell 5 stored in the shell stocker 214 is transferred to the inspection device 110 by the cassette unit 220. The inspection substrate 10 is inspected in the inspection device 110.

The shell 5 is transferred to the inspection device 110, and the electrical characteristics of the plurality of DUTs formed on the inspection substrate 10 are inspected. Specifically, first, the inspection device 110 brings probes (not shown) into electrical contact with the electrode pads 22 of the contact substrate 20. Next, the inspection device 110 applies electrical signals to the plurality of DUTs formed on the inspection substrate 10 via the probes, the electrode pads 22, the wirings 23, the internal circuit 24, the wirings 25, the contact parts 21, and the electrode pads 11 to inspect the electrical characteristics of the plurality of DUTs.

The electrode pads 22 of the contact substrate 20 are formed at a larger pitch than that of the electrode pads 11 of the inspection substrate 10. Since the electrode pads 22 of the contact substrate 20 are formed at a larger pitch than that of the electrode pads 11 of the inspection substrate 10, the probes of the inspection device 110 and the electrode pads 22 can be roughly aligned in the case of inspecting the electrical characteristics of the plurality of DUTs. Since the probes of the inspection device 110 and the electrode pads 22 can be roughly aligned, the inspection device may not include an alignment mechanism for performing highly accurate alignment.

The shell 5 equipped with the inspected inspection substrate 10 is transferred to the shell stocker 214 by the cassette unit 220.

### (Step S60)

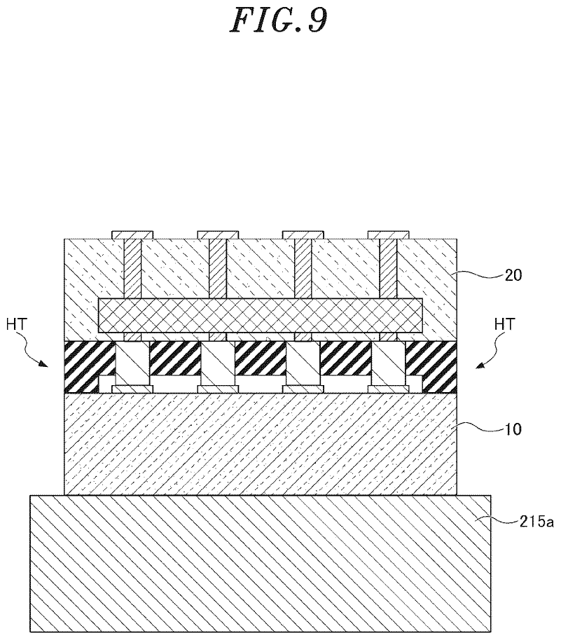

The shell 5 including the inspected inspection substrate 10 is separated from the contact substrate 20 in the attachment/detachment part 215 (step of separating the inspection substrate from the contact substrate). The shell 5 including the inspected inspection substrate 10 is transferred from the shell stocker 214 to the attachment/detachment part 215 by the transfer device 216a of the transfer part 216. The transferred shell 5 is placed on the placing table 215a. FIG. 9 shows a state in which the inspected shell 5 is placed on the placing table 215a.

In the attachment/detachment part 215, heat is applied to the shell 5 from the contact substrate 20 side. As indicated by an arrow HT in FIG. 9, heat is applied from the contact substrate 20 side of the shell 5. When heat is applied, the bonding strength of the adhesive 30 decreases. By applying heat from the contact substrate side, when the contact substrate 20 is separated from the inspection substrate 10, the bonding strength of the adhesive 30 with respect to the inspection substrate becomes higher than the bonding strength of the adhesive 30 with respect to the contact substrate 20.

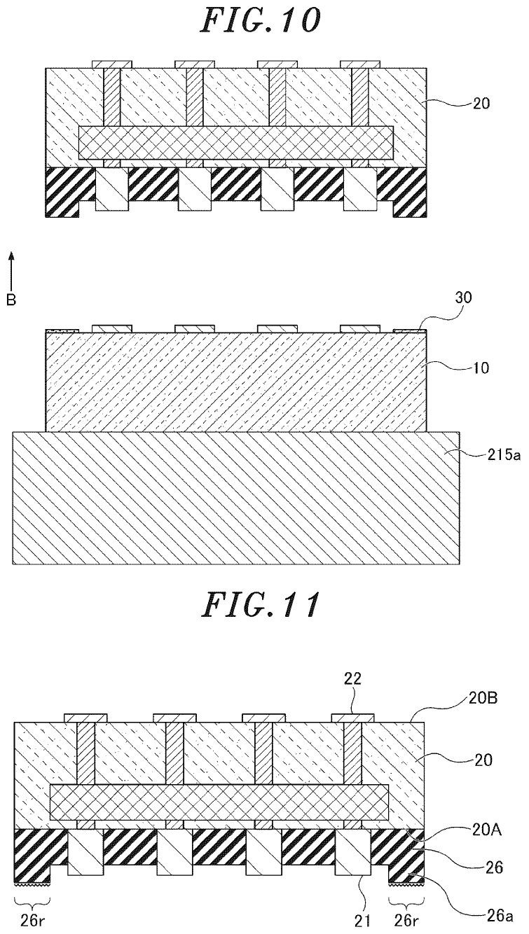

After heating, the contact substrate 20 is separated from the inspection substrate 10. FIG. 10 shows a state in which the contact substrate 20 is separated from the inspection substrate 10. The contact substrate 20 is moved in the direction of an arrow B in FIG. 10 by a robot arm or the like, for example. The contact substrate 20 is separated from the inspection substrate 10 while moving in the direction of the arrow B, i.e., in a direction away from the inspection substrate 10.

As described above, when the contact substrate 20 is separated from the inspection substrate 10, the bonding strength of the adhesive 30 with respect to the inspection substrate 10 is higher than the bonding strength of the adhesive 30 with respect to the contact substrate 20. Thus, the adhesive 30 remains on the inspection substrate 10. On the other hand, the adhesive 30 does not remain on the contact substrate 20.

The contact substrate 20 is separated from the inspection substrate 10, and the inspection substrate 10 and the contact substrate 20 are separated. The inspected inspection substrate 10 is transferred to a next step. The separated contact substrate 20 is reused when the contact portions 21 are cleaned and another inspection substrate 10 is inspected.

In accordance with the inspection method of the present embodiment, when the contact substrate 20 is separated from the inspection substrate 10, the bonding strength of the adhesive 30 with respect to the inspection substrate 10 is higher than the bonding strength of the adhesive 30 with respect to the contact substrate 20. Therefore, in accordance with the inspection method of present embodiment, when the contact substrate 20 is separated from the inspection substrate 10, the adhesive 30 remains on the inspection substrate 10, which makes is possible to suppress the adhesion of the adhesive 30 to the contact substrate 20.

When the contact substrate 20 is separated from the inspection substrate 10, the adhesive 30 is prevented from being adhered to the contact substrate 20 and, thus, the step of cleaning the contact substrate 20 becomes unnecessary, which makes it possible to efficiently reuse the contact substrate 20. Further, although the adhesive 30 is adhered to the inspection substrate 10, the inspection substrate 10 is finally diced, so that the adhesion of the adhesive 30 is ignorable.

In the inspection method of present embodiment, when the contact substrate 20 is separated from the inspection substrate 10, the following steps (A) and (B) are performed in order to make the bonding strength of the adhesive 30 with respect to the inspection substrate 10 higher than the bonding strength of the adhesive 30 with respect to the contact substrate 20. (A) In step S30, the surface treatment is performed on the area 10r of the first main surface 10A of the inspection substrate 10 that is brought into contact with the bonding portion 26a of the contact substrate 20. (B) In step S60, heat is applied to the shell 5 from the contact substrate 20 side.

Further, it is unnecessary to perform the steps (A) and (B) as in the inspection method of the present embedment. For example, in the inspection method, when the contact substrate 20 is separated from the inspection substrate 10, any one of the steps (A) and (B) may be performed in order to make the bonding strength of the adhesive 30 with respect to the inspection substrate 10 higher than the bonding strength of the adhesive 30 with respect to the contact substrate 20.

Further, when the contact substrate 20 is separated from the inspection substrate 10, the type of the adhesive 30 may be appropriately selected in order to make the bonding strength of the adhesive 30 with respect to the inspection substrate 10 higher than the bonding strength of the adhesive 30 with respect to the contact substrate 20. In other words, the adhesive 30 whose bonding strength with respect to the inspection substrate 10 is higher than its bonding strength with respect to the bonding portion 26a of the contact substrate 20 may be used. Further, the usage of the adhesive may be combined with the execution of at least one of (A) and (B).

The inspection substrate 10 is an example of a first substrate, and the contact substrate 20 is an example of a second substrate. The plurality of devices under test (DUT) on the inspection substrate 10 are an example of an inspection object. The electrode pad 11 is an example of a first electrode, the contact portion 21 is an example of a second electrode, and the electrode pad 22 is an example of a third electrode.

In step S30 of the inspection method according to the present embodiment, the surface treatment is performed on the area 10r of the inspection substrate 10. However, the surface treatment may be performed on the area 26r of the bonding portion 26a of the contact substrate 20 that is brought into contact with the first main surface 10A of the inspection substrate 10. FIG. 11 shows the surface treatment performed on the area 26r of the contact substrate 20. The surface treatment is, for example, surface roughening treatment. The surface treatment is treatment that weakens the bonding strength of the adhesive 30 with respect to the contact substrate 20.

The inspection system and the inspection method according to the embodiments of the present disclosure are considered to be illustrative in all respects and not restrictive. The above-described embodiments can be changed and modified in various forms without departing from the scope of the appended claims and the gist thereof. The above-described embodiments may include other configurations without contradicting each other and may be combined without contradicting each other.

This application claims priority to Japanese Patent Application No. 2022-105056 filed on Jun. 29, 2022, the entire contents of which are incorporated herein by reference.

1. An inspection method for inspecting an inspection object of a first substrate, comprising:
(a) preparing the first substrate having a first electrode connected to the inspection object;
(b) preparing a second substrate having a second electrode and a bonding portion which are formed on a first main surface, and having a third electrode formed on a second main surface opposite to the first main surface and electrically connected to the second electrode;
(c) bringing the first electrode and the second electrode into electrical contact with each other and forming a sealed space between the first substrate and the second substrate by bonding the first substrate and the second substrate with an adhesive interposed therebetween;
(d) curing the adhesive;
(e) inspecting the inspection object; and
(f) separating the first substrate from the second substrate,
wherein in said (f), a bonding strength of the adhesive with respect to the first substrate is higher than a bonding strength of the adhesive with respect to the second substrate at the time of being separated the first substrate from the second substrate.

2. The inspection method of claim 1, wherein in said (c), surface treatment is performed on the first substrate or the bonding portion, wherein the surface treatment is a treatment for increasing the bonding strength of the adhesive with respect to the first substrate compared to the bonding strength of the adhesive with respect to the second substrate.

3. The inspection method of claim 2, wherein said (f) includes heating the second substrate.

4. The inspection method of claim 1, wherein said (f) includes heating the second substrate.

5. The inspection method of claim 1, wherein said (c), the adhesive whose the bonding strength with respect to the first substrate is higher than the bonding strength with respect to the second substrate is used.

6. The inspection method of claim 2, wherein said (c), the adhesive whose the bonding strength with respect to the first substrate is higher than the bonding strength with respect to the second substrate is used.

7. The inspection method of claim 3, wherein said (c), the adhesive whose the bonding strength with respect to the first substrate is higher than the bonding strength with respect to the second substrate is used.

8. The inspection method of claim 4, wherein said (c), the adhesive whose the bonding strength with respect to the first substrate is higher than the bonding strength with respect to the second substrate is used.
